(19) United States
(12) Patent Application Publication
(10) Pub. No.: US 2025/0280535 A1
(43) Pub. Date: Sep. 4, 2025

(54) SINGLE-POLY NON-VOLATILE MEMORY CELL

(71) Applicant: eMemory Technology Inc., Hsin-Chu (TW)

(72) Inventors: Hsueh-Wei CHEN, Hsinchu County (TW); Wein-Town Sun, Hsinchu County (TW); Wei-Ren Chen, Hsinchu County (TW)

(21) Appl. No.: 19/006,303

(22) Filed: Dec. 31, 2024

Related U.S. Application Data
(60) Provisional application No. 63/559,234, filed on Feb. 29, 2024.
(60) Provisional application No. 63/682,408, filed on Aug. 13, 2024.

(51) Int. Cl. H10B 41/60; H10B 41/35

(52) U.S. Cl. CPC H10B 41/60; H10B 41/35

(57) ABSTRACT

A single-poly non-volatile memory cell is provided. In the memory cell, a polysilicon gate layer of a gate structure is used as a floating gate of the floating gate transistor. During an ion implantation process, a relatively small amount of dopant is implanted into the polysilicon gate layer. Consequently, the dopant concentration of the polysilicon gate layer is less than the dopant concentration of a merged n-type doped region beside the gate structure. Since the defects in the polysilicon gate layer are reduced, the data retention capability of the memory cell is effectively enhanced.

This application claims the benefit of U.S. provisional application Ser. No. 63/559,234, filed Feb. 29, 2024, and the benefit of U.S. provisional application Ser. No. 63/682,408, filed Aug. 13, 2024, the subject matters of which are incorporated herein by reference.

### FIELD OF THE INVENTION

The present invention relates to a memory cell of a memory, and more particularly to a single-poly non-volatile memory cell.

### BACKGROUND OF THE INVENTION

As is well known, a non-volatile memory includes an array structure. The array structure is composed of a plurality of non-volatile memory cells. Each non-volatile memory cell includes a storage unit. For example, the storage unit is a floating gate transistor. The storage state of the non-volatile memory cell is determined according to the number of charges stored in the floating gate of the floating gate transistor.

In order to be compatible with the standard CMOS manufacturing process, the memory cell of the conventional non-volatile memory is equipped with a single-poly floating gate transistor. The floating gate transistor and associated electronic devices are collaboratively formed as a single-poly non-volatile memory cell.

For example, an erasable programmable single-poly non-volatile memory is disclosed in U.S. Pat. No.8,941,167.

### SUMMARY OF THE INVENTION

An embodiment of the present invention provides a single-poly non-volatile memory cell. The single-poly non-volatile memory cell includes an isolation structure, a first well region, a second well region, a first gate structure, a second gate structure, a first spacer, a second spacer, a first merged doped region, a second merged doped region, a third merged doped region and a fourth merged doped region. The isolation structure is formed on a substrate. The first well region is formed on the substrate. The second well region is formed on the substrate. The isolation structure is located between the first well region and the second well region. The first gate structure and a second gate structure are formed on a surface of the first well region. The second gate structure is extended to the second well region through a surface of the isolation structure. A portion of the second well region is covered by the second gate structure. The first spacer is formed on a sidewall of the first gate structure. The second spacer is formed on a sidewall of the second gate structure. The first merged doped region is formed under a surface of the first well region and located beside a first side of the first gate structure. The second merged doped region is formed under the surface of the first well region. The second merged doped region is arranged between a second side of the first gate structure and a first side of the second gate structure. The third merged doped region is formed under the surface of the first well region and located beside a second side of the second gate structure. The fourth merged doped region is formed under a surface of the second well region and located beside the second gate structure. The first gate structure includes a first gate oxide layer and a first polysilicon gate layer. The second gate structure includes a second gate oxide layer and a second polysilicon gate layer. A dopant concentration of the second polysilicon gate layer above the second well region is less than a dopant concentration of the fourth merged doped region.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1K schematically illustrate the steps of a method of manufacturing a single-poly non-volatile memory cell according to a first embodiment of the present invention;

FIG. 1L is a schematic equivalent circuit diagram of the single-poly non-volatile memory cell according to the first embodiment of the present invention;

FIG. 2A is a schematic circuit diagram the bias voltages of performing a program action on the memory cell according to the first embodiment of the present invention;

FIG. 2B is a schematic circuit diagram the bias voltages of performing an erase action on the memory cell according to the first embodiment of the present invention;

FIG. 2C is a schematic circuit diagram the bias voltages of performing a read action on the memory cell according to the first embodiment of the present invention;

FIGS. 3A to 3C schematically illustrate the steps of a method of manufacturing a single-poly non-volatile memory cell according to a second embodiment of the present invention; and

FIGS. 4A to 4D schematically illustrate the steps of a method of manufacturing a single-poly non-volatile memory cell according to a third embodiment of the present invention.

### DETAILED DESCRIPTION OF PREFERRED EMBODIMENTS

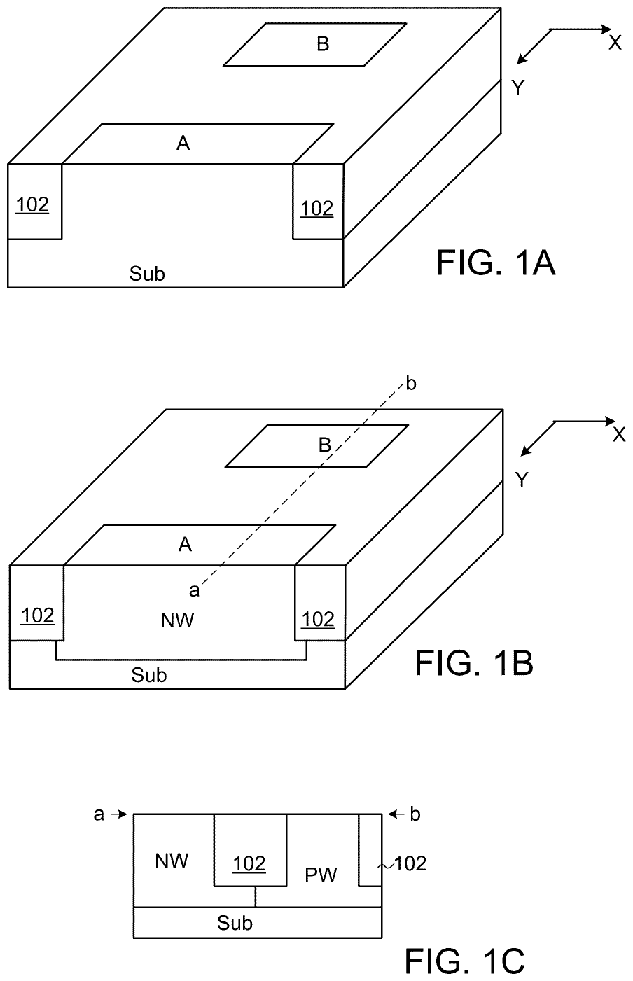

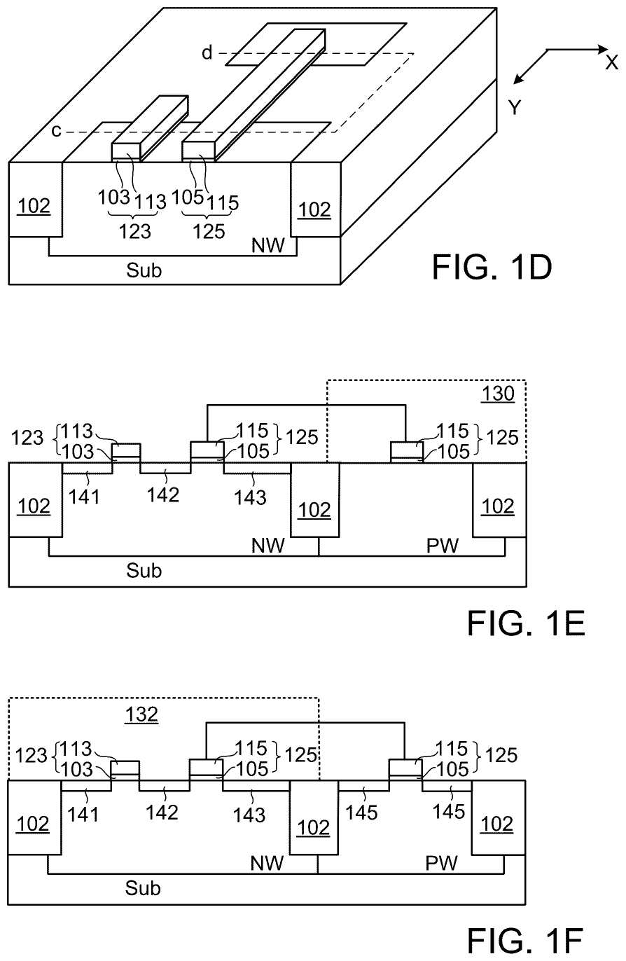

FIGS. 1A to 1K schematically illustrate the steps of a method of manufacturing a single-poly non-volatile memory cell according to a first embodiment of the present invention. FIG. 1L is a schematic equivalent circuit diagram of the single-poly non-volatile memory cell according to the first embodiment of the present invention. Hereinafter, the single-poly non-volatile memory cell is referred as a memory cell.

As shown in FIG. 1A, an isolation structure forming step is performed. Firstly, an isolation structure such as a shallow trench isolation (STI) structure 102 is formed on a substrate sub. Due to the isolation structure 102, a region A and a region B is defined. For example, the substrate sub is a p-type substrate, an n-type substrate, a glass substrate, or any other appropriate substrate. That is, the substrate sub is covered by the isolation structure 102, but only the surface of the p-type substrate corresponding to the region A and the region B is exposed. In the memory cell of the first embodiment, two series-connected p-type transistors are formed in the region A, and an n-type transistor is formed in the region B.

Then, as shown in FIG. 1B, a first well region forming step and a second well region forming step are performed. In the first well region forming step, the region A is exposed, and the region B is covered. Consequently, a first well region is formed. For example, the first well region is an N-well region. In other words, the N-well region is formed under the surface of the region A. In the second well region forming step, the region B is exposed, and the region A is covered. Consequently, a second well region is formed. For example, the second well region is a P-well region. In other words, the P-well region is formed under the surface of the region B. It is noted that the sequence of the first well region forming step and the second well region forming step is not restricted.

FIG. 1C is a schematic cross-sectional view illustrating the resulting structure of FIG. 1B and taken along with the line a-b. As shown in FIG. 1C, the N-well region is formed under the surface of the region A, the P-well region is formed under the surface of the region B, and the isolation structure 102 is located between the N-well region and the P-well region. In addition, the portion of the N-well region and the portion of the P-well region underlying the isolation structure 102 are in contact with each other.

As shown in FIG. 1D, a gate structure forming step is performed. Firstly, two gate oxide layers 103 and 105 are formed. Then, two polysilicon gate layers 113 and 115 are formed on the two gate oxide layers 103 and 105, respectively. Consequently, two gate structures 123 and 125 are formed.

Please refer to FIG. 1D again. The two gate structures 123 and 125 are formed on the surface of the region A. In addition, the region A is divided into three sub-regions by the two gate structures 123 and 125. The gate structure 125 is extended externally from the region A to the region B through the surface of the isolation structure 102. In addition, a portion of the region B is covered by the gate structure 125. The polysilicon gate layer 115 of the gate structure 125 is served as a floating gate. The polysilicon gate layer 113 of the gate structure 123 is served as a select gate.

Subsequently, a doped region forming step and a conducting line forming step are performed. In the following drawings, the cross-sectional view of FIG. 1D and taken along the line c-d will be shown to describe the doped region forming step and the conducting line forming step.

As shown in FIG. 1E, a photoresist layer 130 indicated by dashed lines is formed to cover the region B and the overlying gate structure 125. Then, a p-type lightly doped drain process (PLDD process) is performed on the region A with the gate structures 123 and 125 serving as the hard masks. Consequently, three p-type lightly doped drain regions (PLDD regions) 141, 142 and 143 are formed under the surface of the N-well region NW corresponding to the region A. The PLDD region 141 is formed under the surface of the N-well region NW and located beside the first side of the gate structure 123. The PLDD region 142 is formed under the surface of the N-well region NW and arranged between the second side of the gate structure 123 and the first side of the gate structure 125. The PLDD region 143 is formed under the surface of the N-well region NW and located beside the second side of the gate structure 125.

Please refer to FIG. 1F. After the photoresist layer 130 is removed, a photoresist layer 132 indicated by dashed lines is formed to cover the region A and the overlying gate structures 123 and 125. Then, an n-type lightly doped drain process (NLDD process) is performed on the region B with the gate structure 125 serving as the hard mask. Consequently, an n-type lightly doped drain region (NLDD region) 145 is formed under the surface of the P-well region PW corresponding to the region B. In addition, the NLDD region 145 is located beside the gate structure 125.

Please refer to FIG. 1G. After the photoresist layer 132 is removed, a spacer 153 is formed on the sidewall of the gate structure 123, and a spacer 155 is formed on the sidewall of the gate structure 125.

As shown in FIG. 1H, a photoresist layer 134 indicated by dashed lines is formed to cover the region B and the overlying gate structure 125 and spacer 155. Please refer to FIG. 1H. Then, a p-type ion implantation process is performed on the region A by using the two gate structures 123 and 125 and the two spacers 153 and 155 as hard masks. Consequently, three p-type ion implantation regions 161, 162 and 163 indicated by oblique lines are formed on three sub-regions of the region A uncovered by the two gate structures 123 and 125 and the two spacers 153 and 155. Especially, the dopant concentration of the p-type ion implantation regions 161, 162 and 163 is greater than the dopant concentration of the PLDD regions 141, 142 and 143. The p-type ion implantation regions 161, 162 and 163 are the source/drain region.

Please refer to FIG. 1H again. The PLDD region 141 and the p-type ion implantation region 161 are partially overlapped with each other. In addition, the PLDD region 141 and the p-type ion implantation region 161 are collaboratively formed as a merged p-doped region 171. The PLDD region 142 and the p-type ion implantation region 162 are partially overlapped with each other. In addition, the PLDD region 142 and the p-type ion implantation region 162 are collaboratively formed as a merged p-doped region 172. The PLDD region 143 and the p-type ion implantation region 163 are partially overlapped with each other. In addition, the PLDD region 143 and the p-type ion implantation region 163 are collaboratively formed as a merged p-doped region 173. The merged p-doped region 171 is formed under the surface of the N-well region NW and located beside the first side of the gate structure 123. The merged p-doped region 172 is formed under the surface of the N-well region NW and arranged between the second side of the gate structure 123 and the first side of the gate structure 125. The merged p-doped region 173 is formed under the surface of the N-well region NW and located beside the second side of the gate structure 125.

Furthermore, when the p-type ion implantation process is performed, the two gate structures 123 and 125 are used as the hard masks. Consequently, the polysilicon gate layers 113 and 115 over the region A are formed as the p-type polysilicon gate layers. The dopant concentration of the p-type polysilicon gate layers is equal to the dopant concentration of the merged p-doped region 173.

Please refer to FIG. 11. After the photoresist layer 134 is removed, a photoresist layer 136 indicated by dashed lines is formed to cover the region A, the overlying gate structures 123, 125 and the overlying spacers 153, 155. Then, an n-type ion implantation process is performed on the region B by using the gate structure 125 and the spacer 155 as hard masks.

Consequently, an n-type ion implantation region 165 indicated by oblique lines is formed in the region B uncovered by the gate structure 125 and the spacer 155. Especially, the dopant concentration of the n-type ion implantation region 165 is greater than the dopant concentration of the NLDD region 145.

Please refer to FIG. 11 again. The NLDD region 145 and the n-type ion implantation region 165 are partially overlapped with each other. In addition, the NLDD region 145 and the n-type ion implantation region 165 are collaboratively formed as a merged n-doped region 175. In addition, the merged n-doped region 175 is located beside the gate structure 125.

Furthermore, when the n-type ion implantation process is performed, the gate structure 125 is used as the hard mask. Consequently, the polysilicon gate layer 115 over the region B is formed as the n-type polysilicon gate layers. The dopant concentration of the n-type polysilicon gate layer is equal to the dopant concentration of the merged n-doped region 175.

Please refer to FIG. 1J. After the photoresist layer 136 is removed and the conducting line forming step is completed, the memory cell of the first embodiment is fabricated.

That is, the merged p-type doped region 171 is connected with a source line SL, the merged p-type doped region 173 is connected with a bit line BL, the merged n-type doped region 175 is connected with an erase line EL, and the polysilicon gate layer 113 is connected with a select gate line SG. The three-dimensional view of the resulting structure of FIG. 1J is shown in FIG. 1K.

In the region A, the gate structure 123 and the merged p-type doped regions 171 and 172 on its two sides are collaboratively formed as a select transistor. In addition, the gate structure 125 and the two merged p-doped regions 172 and 173 on its two sides are collaboratively formed as a floating gate transistor. The polysilicon gate layer 115 of the gate structure 125 is the floating gate of the floating gate transistor. Furthermore, the floating gate transistor and the select transistor are p-type transistors.

As mentioned above, the gate structure 125 is extended externally from the region A to the surface of the region B. Consequently, the gate structure 125 and the merged n-doped region 175 corresponding to the region B are collaboratively formed as an n-type transistor. The two drain/source terminals of the n-type transistor are connected with each other. Consequently, the n-type transistor is connected as an n-type MOS capacitor.

As shown in FIG. 1L, the memory cell includes a select transistor M_{S}, a floating gate transistor M_{F} and a MOS capacitor C_{MOS}. The gate terminal of the select transistor M_{S} is connected with the select gate line SG. The first drain/source terminal of the select transistor M_{S} is connected with the source line SL. The first drain/source terminal of the floating gate transistor M_{F} is connected with the second drain/source terminal of the select transistor M_{S}. The second drain/source terminal of the floating gate transistor M_{F} is connected with the bit line BL. The first terminal of the MOS capacitor CMOS is connected with the floating gate 115 of the floating gate transistor M_{F}. The second terminal of the MOS capacitor C_{MOS} is connected with the erase line EL.

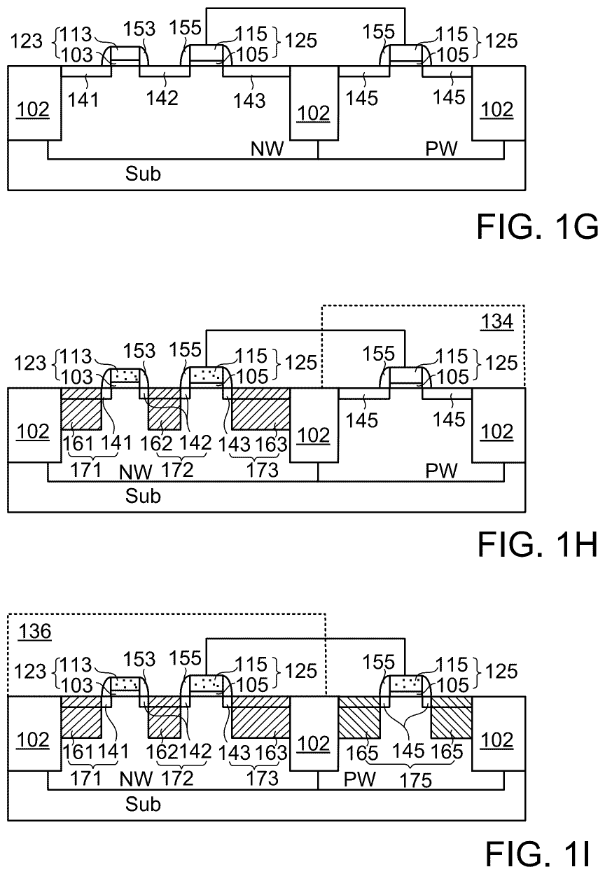

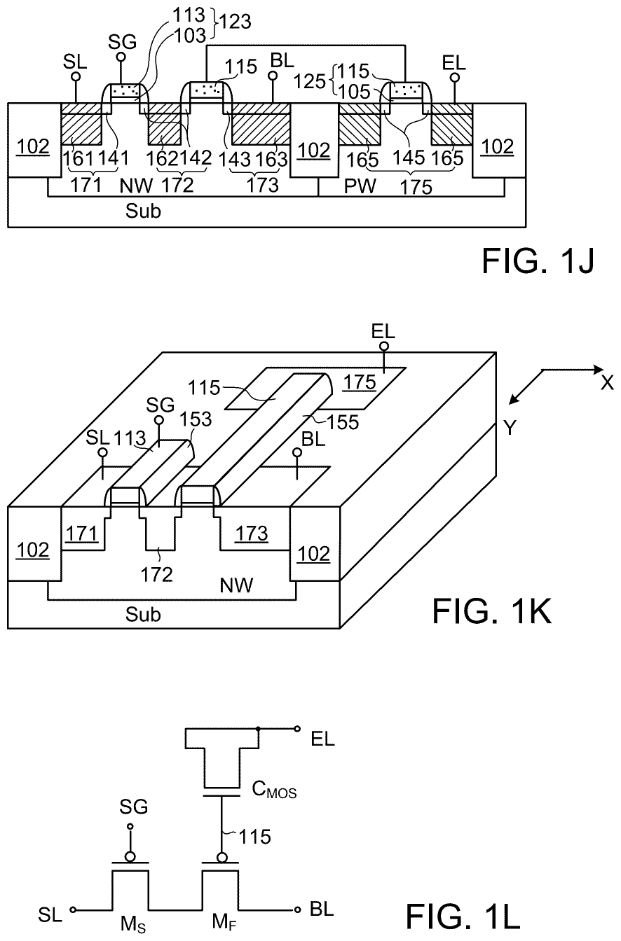

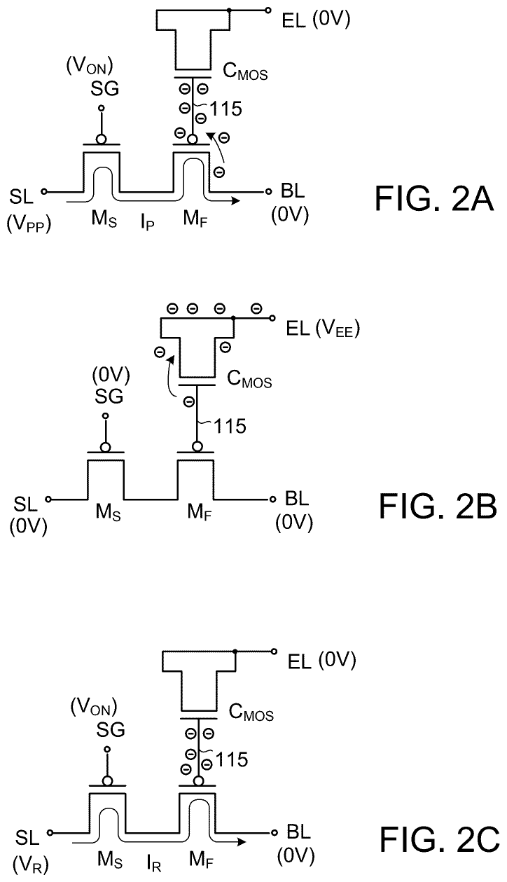

FIG. 2A is a schematic circuit diagram the bias voltages of performing a program action on the memory cell according to the first embodiment of the present invention. FIG. 2B is a schematic circuit diagram the bias voltages of performing an erase action on the memory cell according to the first embodiment of the present invention. FIG. 2C is a schematic circuit diagram the bias voltages of performing a read action on the memory cell according to the first embodiment of the present invention.

Please refer to FIG. 2A. When the program action is performed, the source line SL receives a program voltage V_{PP}, the select gate line SG receives an on voltage V_{ON}, the bit line BL receives a ground voltage (0V), and the erase line EL receives the ground voltage (0V). For example, the program voltage V_{PP} is 9V, and the on voltage V_{ON} is 0V.

When the program action is performed, the select transistor M_{S} is turned on, and a program current I_{P} is generated between the bit line BL and the source line SL. Consequently, when the hot carriers (e.g., electrons) of the program current I_{P} flow through a channel region corresponding to the floating gate 115, a channel hot electron effect (CHE effect) is generated. Due to the CHE effect, electrons are injected into the floating gate 115.

Please refer to FIG. 2B. When the erase action is performed, the source line SL receives the ground voltage (0V), the bit line BL receives the ground voltage (0V), the select gate line SG receives the ground voltage (0V), and the erase line EL receives an erase voltage V_{EE}. For example, the erase voltage V_{EE} is 12V.

When the erase action is performed, the select transistor M_{S} is turned off. Under this circumstance, a Fowler-Nordheim Tunneling (FN) effect is generated at the two terminals of the MOS transistor C_{MOS}. Consequently, hot carriers are ejected from the floating gate 115 to the erase line EL.

Please refer to FIG. 2C. When the read action is performed, the source line SL receives a read voltage V_{R}, the bit line BL receives the ground voltage (0V), the select gate line SG receives the on voltage V_{ON}, and the erase line EL receives the ground voltage (0V). For example, the read voltage V_{R} is 5V.

When a read action is performed, the select transistor M_{S} is turned on, and a read current I_{R} is generated between the bit line BL and the source line SL. The storage state of the memory cell can be determined according to the magnitude of the read current I_{R}. For example, in case that no electrons are stored in the floating gate 115, the magnitude of the read current IR is very low (e.g., nearly zero). Consequently, it is determined that the memory cell is in a first storage state. Whereas, in case that electrons are stored in the floating gate 115, the magnitude of the read current I_{R} is very high. Under this circumstance, it is determined that the memory cell is in a second storage state.

In the ion implantation process of manufacturing the memory cell of

the first embodiment, ions are accelerated to the high energy state. Consequently, ions are impinged on a target and implanted in the target.

Generally, when the n-type ion implantation process is performed, arsenic ions are used as dopant. For example, when the n-type ion implantation process is performed on the resulting structure of FIG. 1I, the gate structure 125 is used as the hard mask, and arsenic ions are implanted into the P-well region PW corresponding to the region B. Consequently, the n-type ion implantation region 165. In addition, arsenic ions are implanted into the polysilicon gate layer 115, so that the n-type polysilicon gate layer is formed.

After the high-energy arsenic ions are impinged on the polysilicon gate layer 115, many defects are generated in the polysilicon gate layer 115. As mentioned above, the polysilicon gate layer 115 of the gate structure 125 is the floating gate of the floating gate transistor MF for storing the injected electrons. Due to the defects in the polysilicon gate layer 115, a leakage path is generated. Consequently, the stored electrons are escaped from the floating gate, and the data retention capability of the memory cell is deteriorated.

In order to improve the data retention capability of the memory cell, the manufacturing process of the first embodiment needs to be modified. For example, in a second embodiment, the gate structure and the spacer are covered by a photoresist layer when the ion implantation process is performed.

Consequently, the defects in the polysilicon gate layer will be reduced, and the data retention capability of the memory cell will be increased. Since the manufacturing process is modified, the structure of the memory cell in the second embodiment is distinguished from the structure of the memory cell in the first embodiment.

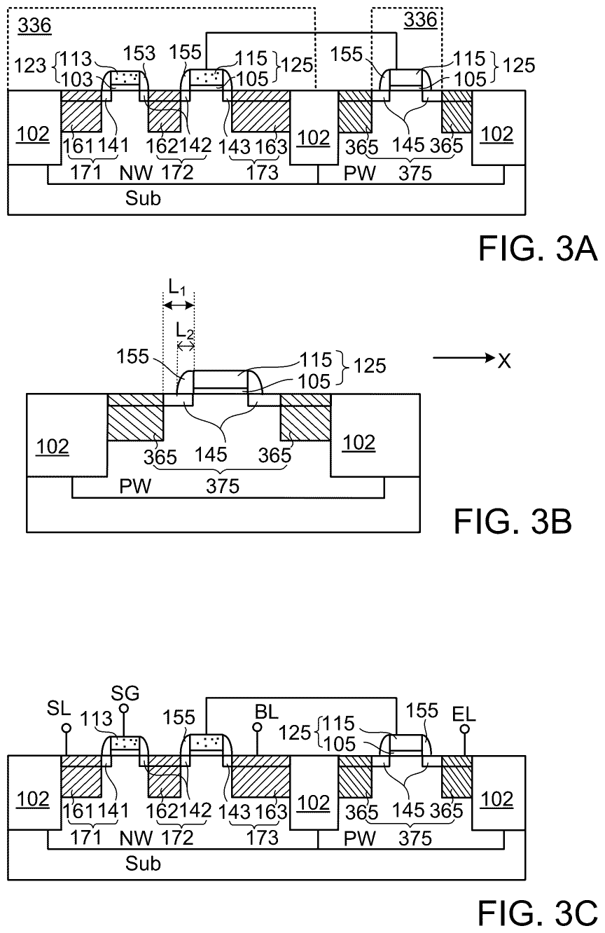

FIGS. 3A to 3C schematically illustrate the steps of a method of manufacturing a single-poly non-volatile memory cell according to a second embodiment of the present invention. The steps of this embodiment before the step shown in FIG. 1H are similar to those of the first embodiment. For succinctness, only the steps after the step shown in FIG. 1H will be described as follows.

Please refer to FIG. 3A. After the photoresist layer 134 shown in FIG. 1H is removed, a photoresist layer 336 indicated by dashed lines is formed to cover the region A, the overlying gate structures 123, 125 and the overlying spacers 153, 155. The photoresist layer 336 also covers the gate structure 125 and the spacer 155 corresponding to the region B. In addition, a smaller portion of the surface of the region B beside the spacer 155 is covered by the photoresist layer 336, and a larger portion of the surface of the region B is exposed.

Then, an n-type ion implantation process is performed on the region B. Consequently, an n-type ion implantation region 365 indicated by oblique lines is formed in the region B uncovered by the photoresist layer 336. Especially, the dopant concentration of the n-type ion implantation region 365 is greater than the dopant concentration of the NLDD region 145.

FIG. 3B is a schematic cross-sectional view illustrating an enlarged portion of the structure shown in FIG. 3A and near the region B. As shown in FIG. 3B, a first portion of the NLDD region 145 and a portion of the n-type ion implantation region 365 are overlapped with each other, and a second portion of the NLDD region 145 including the portions directly and not directly below the spacer 155) is not overlapped with the n-type ion implantation region 365. In addition, the NLDD region 145 and the n-type ion implantation region 365 are collaboratively formed as a merged n-doped region 375. In addition, the merged n-doped region 375 is located beside the gate structure 125.

When the n-type ion implantation process is performed, a small portion of the surface of the region B beside the spacer 155 is covered by the photoresist layer 336. Consequently, in the x-direction, the width of the second portion of the NLDD region 145 in the merged n-doped region 375 is larger than the width of the spacer 155. As shown in FIG. 3B, the second portion of the NLDD region 145 in the merged n-doped region 375 has a width L₁, and the spacer 155 has a width L₂, wherein L₁ is greater than L₂. For example, the width L₁ is greater than 0.5 μm and less than 5 μm, and the width L₂ is greater than 0 μm and less than 0.5 μm. It should be noted that embodiments are not limited to the width of the photoresist layers 336 over the gate structure 125 shown in FIG. 3A, as other photoresist layers may be used in some embodiments. For example, the width of the photoresist layers 336 over the gate structure 125 can be equal to the width of the polysilicon gate layer 115 plus the width of the spacers such that the width L₁ is equal to the width L₂.

Furthermore, when the n-type ion implantation process is performed, the gate structure 125 corresponding to the region B is covered by the photoresist layer 336. Consequently, the dopant concentration of the polysilicon gate layer 115 is less than the dopant concentration of the merged n-doped region 375. When compared with the first embodiment, the gate structure 125 corresponding to the region B is covered by the photoresist layer 336 according to the second embodiment. After the n-type ion implantation process is completed, the defects in the polysilicon gate layer 115 will be largely reduced, and the data retention capability of the memory cell can be effectively enhanced.

Please refer to FIG. 3C. After the photoresist layer 336 is removed and the conducting line forming step is completed, the memory cell of the second embodiment is fabricated. That is, the merged p-type doped region 171 is connected with the source line SL, the merged p-type doped region 173 is connected with the bit line BL, the merged n-type doped region 375 is connected with the erase line EL, and the polysilicon gate layer 113 is connected with the select gate line SG.

The equivalent circuit of the memory cell in the second embodiment is identical to the equivalent circuit of the memory cell in the first embodiment.

The bias voltages of performing the program action, the erase action and the read action are similar, and not redundantly described herein.

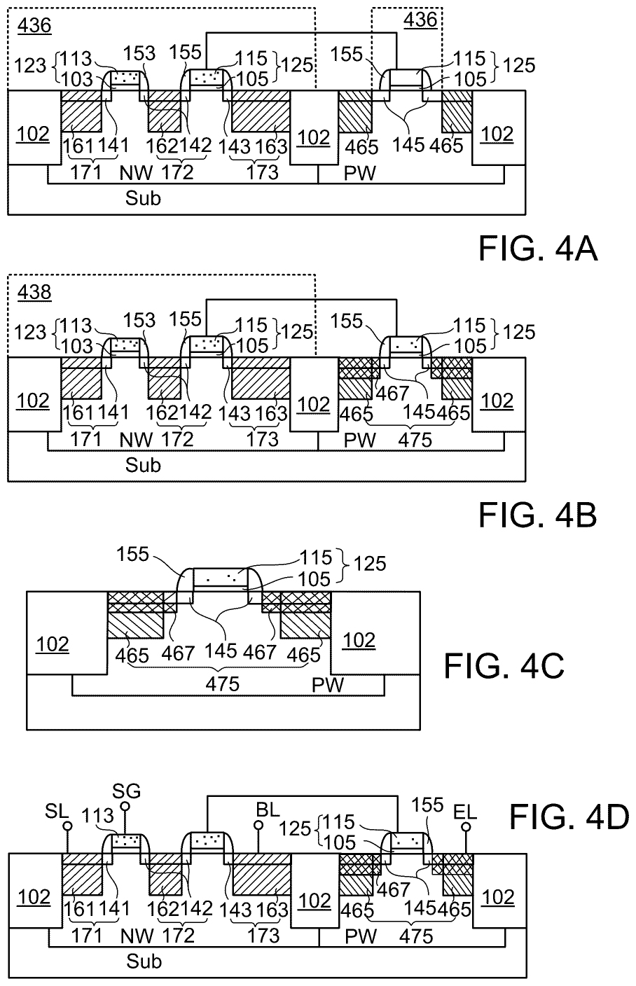

FIGS. 4A to 4D schematically illustrate the steps of a method of manufacturing a single-poly non-volatile memory cell according to a third embodiment of the present invention. The steps of this embodiment before the step shown in FIG. 1H are similar to those of the first embodiment. For succinctness, only the steps after the step shown in FIG. 1H will be described as follows.

Please refer to FIG. 4A. After the photoresist layer 134 shown in FIG. 1H is removed, a photoresist layer 436 indicated by dashed lines is formed to cover the region A, the overlying gate structures 123, 125 and the overlying spacers 153, 155. The photoresist layer 436 also covers the gate structure 125 and the spacer 155 corresponding to the region B. In addition, a smaller portion of the surface of the region B beside the spacer 155 is covered by the photoresist layer 436, and a larger portion of the surface of the region B is exposed. It should be noted that embodiments are not limited to the width of the photoresist layers 336, 436 over the gate structure 125 shown in FIG. 3A and FIG. 4A, as other photoresist layers may be used in some embodiments. For example, the width of the photoresist layers 336, 436 over the gate structure 125 can be equal to the width of the polysilicon gate layer 115.

Then, a first n-type ion implantation process is performed on the region B. Consequently, an n-type ion implantation region 465 indicated by oblique lines is formed in the region B uncovered by the photoresist layer 436. Especially, the dopant concentration of the n-type ion implantation region 465 is greater than the dopant concentration of the NLDD region 145.

Please refer to FIG. 4B. After the photoresist layer 436 is removed,

another photoresist layer 438 is formed. The photoresist layer 438 covers the region A, the overlying gate structures 123, 125 and the overlying spacers 153, 155.

Then, a second n-type ion implantation process is performed on the region B by using the gate structure 125 and the spacer 155 as hard masks. Consequently, a second n-type ion implantation region 467 indicated by oblique lines are formed in the region B uncovered by the gate structure 125 and the spacer 155.

In this embodiment, the provided energy in the first n-type ion implantation process is greater than the provided energy in the second n-type ion implantation process. Consequently, the depth of the first n-type ion implantation region 465 is greater than the depth of the second n-type ion implantation region 467.

FIG. 4C is a schematic cross-sectional view illustrating an enlarged portion of the structure shown in FIG. 4B and near the region B. As shown in FIG. 4C, the NLDD region 145, the first n-type ion implantation region 465 and the second n-type ion implantation region 467 are collaboratively formed as a merged n-doped region 475. The merged n-doped region 475 is located beside the gate structure 125. In addition, a first portion of the NLDD region 145 in the merged n-doped region 475 is overlapped with one of the n-type ion implantation region 465, 467, and a second portion of the NLDD region 145 in the merged n-doped region 475 is not overlapped with the first n-type ion implantation region 465, and the second portion of the NLDD region 145 in the merged n-doped region 475 is not overlapped with the second n-type ion implantation region 467.

As mentioned above, the gate structure 125 and the spacer 155 are used as the masks when the second n-type ion implantation process is performed. Consequently, the width of the second portion of the NLDD region 145 in the merged n-doped region 475 is equal to the width of the spacer 155.

As mentioned above, the gate structure 125 corresponding to the region B is covered by the photoresist layer 436 when the first n-type ion implantation process is performed. Consequently, after the second n-type ion implantation process is completed, it is assured that the dopant concentration of the polysilicon gate layer 115 is substantially equal to the dopant concentration of the second n-type ion implantation region 467 and the dopant concentration of the polysilicon gate layer 115 is less than the dopant concentration of the merged n-doped region 475. For example, the dopant concentration of the polysilicon gate layer 115 is A (particle/cm³), and the dopant concentration of the merged n-doped region 475 is B (particle/cm³). Preferably, A<(B×40%). That is, the dopant concentration of the polysilicon gate layer 115 is less than 40% of the dopant concentration of the merged n-doped region 475.

Furthermore, when the second n-type ion implantation process is performed, less energy is provided. Consequently, the defects in the polysilicon gate layer 115 will be largely reduced when compared with the first embodiment and the third embodiment. Consequently, the data retention capability of the memory cell can be effectively enhanced.

Please refer to FIG. 4D. After the photoresist layer 438 is removed and the conducting line forming step is completed, the memory cell of the third embodiment is fabricated. That is, the merged p-type doped region 171 is connected with the source line SL, the merged p-type doped region 173 is connected with the bit line BL, the merged n-type doped region 475 is connected with the erase line EL, and the polysilicon gate layer 113 is connected with the select gate line SG.

The equivalent circuit of the memory cell in the third embodiment is identical to the equivalent circuit of the memory cell in the first embodiment. The bias voltages of performing the program action, the erase action and the read action are similar, and not redundantly described herein.

From the above descriptions, the present invention provides the single-poly non-volatile memory cell. In the memory cell, the polysilicon gate layer 115 of the gate structure 125 is used as the floating gate of the floating gate transistor. Furthermore, during the ion implantation process, a relatively small amount of dopant is implanted into the polysilicon gate layer 115. Consequently, the dopant concentration of the polysilicon gate layer 115 is less than the dopant concentration of the merged n-type doped region 475 beside the gate structure 125. Since the defects in the polysilicon gate layer 115 are largely reduced, the data retention capability of the memory cell is effectively enhanced.

In the above embodiments, the select transistor M_{S} and the floating gate transistor M_{F} are p-type transistors. It is noted that the types of these transistors are not restricted. For example, in another embodiment, the manufacturing process of the memory cell is modified, and thus the select transistor M_{S} and the floating gate transistor M_{F} are n-type transistors.

For example, in the structure of FIG. 1K, the first well region under the surface of the region A is modified as a P-well region PW, and the merged doped regions 171, 172 and 173 are modified as merged n-type doped regions. Consequently, the select transistor M_{S} and the floating gate transistor M_{F} are n-type transistors. Similarly, in case that the floating gate transistor M_{F} is the n-type transistor, the technologies of the second embodiment and the third embodiment can be applied in the process of forming the merged doped regions 171, 172 and 173 corresponding to the region A. Since the defects in the polysilicon gate layer 115 of the gate structure 125 is largely reduced, the data retention capability of the memory cell is effectively enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A single-poly non-volatile memory cell, comprising:
a substrate;
an isolation structure formed on the substrate;
a first well region formed on the substrate;
a second well region formed on the substrate, wherein the isolation structure is located between the first well region and the second well region;
a first gate structure and a second gate structure formed on the first well region, wherein the second gate structure is extended to the second well region through a surface of the isolation structure, and a portion of the second well region is covered by the second gate structure;
a first spacer formed on a sidewall of the first gate structure;
a second spacer formed on a sidewall of the second gate structure;
a first merged doped region formed under a surface of the first well region, and located beside a first side of the first gate structure;
a second merged doped region formed under the surface of the first well region, and arranged between a second side of the first gate structure and a first side of the second gate structure;
a third merged doped region formed under the surface of the first well region, and located beside a second side of the second gate structure; and
a fourth merged doped region formed under a surface of the second well region, and located beside the second gate structure,
wherein the first gate structure comprises a first gate oxide layer and a first polysilicon gate layer, the second gate structure comprises a second gate oxide layer and a second polysilicon gate layer, and a dopant concentration of the second polysilicon gate layer above the second well region is less than a dopant concentration of the fourth merged doped region.

2. The single-poly non-volatile memory cell as claimed in claim 1, wherein the first merged doped region, the first gate structure and the second merged doped region are collaboratively formed as a select transistor, the second merged doped region, the second gate structure and the third merged doped region are collaboratively formed as a floating gate transistor, and the second gate structure and the fourth merged doped region are collaboratively formed as a MOS capacitor.

3. The single-poly non-volatile memory cell as claimed in claim 2, wherein a gate terminal of the select transistor is connected with a select gate line, a first drain/source terminal of the select transistor is connected with a source line, a first drain/source terminal of the floating gate transistor is connected with a second drain/source terminal of the select transistor, a second drain/source terminal of the floating gate transistor is connected with a bit line, a first terminal of the MOS capacitor is connected with a floating gate of the floating gate transistor, and a second terminal of the MOS capacitor is connected with an erase line.

4. The single-poly non-volatile memory cell as claimed in claim 2, wherein the select transistor and the floating gate transistor are p-type transistors, the second gate structure and the fourth merged doped region are collaboratively formed as an n-type transistor, and a first drain/source terminal and a second drain/source terminal of the n-type transistor are connected with each other to form an n-type MOS capacitor.

5. The single-poly non-volatile memory cell as claimed in claim 2, wherein the second gate structure and the fourth merged doped region are collaboratively formed as a first transistor, and the first transistor, the select transistor and the floating gate transistor are n-type transistors, wherein a first drain/source terminal and a second drain/source terminal of the first transistor are connected with each other to form an n-type MOS capacitor.

6. The single-poly non-volatile memory cell as claimed in claim 1, wherein the fourth merged doped region comprises a lightly doped drain region and an ion implantation region, wherein a first portion of the lightly doped drain region is overlapped with a portion of the ion implantation region, and a second portion of the lightly doped drain region is not overlapped with the ion implantation region.

7. The single-poly non-volatile memory cell as claimed in claim 6, wherein the fourth merged doped region is a merged n-type doped region, the lightly doped drain region is an n-type lightly doped drain region, and the ion implantation region is an n-type ion implantation region.

8. The single-poly non-volatile memory cell as claimed in claim 6, wherein a width of the second portion of the lightly doped drain region is equal to or greater than a width of the second spacer.

9. The single-poly non-volatile memory cell as claimed in claim 8, wherein the width of the second portion of the lightly doped drain region is greater than 0.5 μm and less than 5 μm, and the width of the second spacer is greater than 0 μm and less than 0.5 μm.

10. The single-poly non-volatile memory cell as claimed in claim 1, wherein the fourth merged doped region comprises a lightly doped drain region, a first ion implantation region and a second ion implantation region, wherein a first portion of the lightly doped drain region is overlapped with one of the first ion implantation region and the second ion implantation region, and a second portion of the lightly doped drain region is not overlapped with the first ion implantation region, and the second portion of the lightly doped drain region is not overlapped with the second ion implantation region.

11. The single-poly non-volatile memory cell as claimed in claim 10, wherein the fourth merged doped region is a merged n-type doped region, the first lightly doped drain region is a first n-type lightly doped drain region, the first ion implantation region is a first n-type ion implantation region, and the second ion implantation region is a second n-type ion implantation region.

12. The single-poly non-volatile memory cell as claimed in claim 10, wherein a width of the second portion of the lightly doped drain region is equal to a width of the second spacer.

13. The single-poly non-volatile memory cell as claimed in claim 10, wherein a depth of the first ion implantation region is greater than a depth of the second ion implantation region, a dopant concentration of the second polysilicon gate layer above the second well region is equal to a dopant concentration of the second ion implantation region, and the dopant concentration of the second polysilicon gate layer above the second well region is less than a dopant concentration of the merged n-doped region.

14. The single-poly non-volatile memory cell as claimed in claim 13, wherein the dopant concentration of the second polysilicon gate layer above the second well region is less than 40% of the dopant concentration of the fourth merged doped region.
